(19) United States
(12) Patent Application Publication
(10) Pub. No.: US 2007/0029621 A1
(43) Pub. Date: Feb. 8, 2007

(54) Semiconductor integrated circuit device

(75) Inventor: Kyoka Tatsumi, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC ELECTRONICS CORPORATION, Kanagawa (JP)

(21) Appl. No.: 11/486,128

(22) Filed: Jul. 14, 2006

(30) Foreign Application Priority Data
Aug. 5, 2005 (JP) 2005-228069
Jan. 27, 2006 (JP) 2006-019256

(51) Int. Cl. H01L 29/76

(52) U.S. Cl. 257/371

(57) ABSTRACT

Cell placement areas in which a plurality of standard cells are placed in bands are provided on a semiconductor substrate of a semiconductor integrated circuit device. The cell placement areas have N- and P-wells formed in the cell placement areas, and a deep N-well formed in the substrate underneath the N- and P-wells. Substrate-bias supply cells, which are placed in each of the cell placement areas and have one side the height of which is the same as that of the bands of the cell placement areas, apply a substrate bias to the standard cells through the P-well. The substrate-bias supply cells are disposed one after another in the vertical direction and periodically along the horizontal direction. Many wiring traces for supplying substrate bias are eliminated by using the deep N-well and P-well as wiring routes regarding a power supply for supplying substrate bias.

### FIELD OF THE INVENTION

This invention relates to a semiconductor integrated circuit device and, more particularly, to a semiconductor integrated circuit device having substrate-bias supply cells for controlling substrate potential.

### BACKGROUND OF THE INVENTION

LSI chips used in recent mobile devices such as mobile terminals are required to execute high-speed processing and to consume little power. These requirements generally are mutually contradictory; if frequency is raised to execute high-speed processing, heat is evolved and power consumption increases. In order to deal with these mutually contradictory requirements, a substrate biasing technique has been adopted. This involves applying a potential, which is different from that of a transistor source, to the substrate and controlling substrate potential to thereby reduce leakage when the transistor is cut off. In order to control substrate bias with this substrate biasing technique, a substrate potential for control is separately required in addition to the usual power-supply potential.

An example of a semiconductor integrated circuit device having wiring for supplying a substrate bias that controls substrate potential is disclosed in the specification of Japanese Patent Kokai Publication No. JP-P2001-148464A (see FIG. 1 thereof). This semiconductor integrated circuit device has the structure shown in FIG. 10. Power-supply voltage VDD lines (VDD) 101 and ground voltage VSS lines (GND) 102 are wired alternatingly as a first wiring layer on a semiconductor substrate at regular intervals along the horizontal direction in FIG. 10. Logic cells CA are arranged along the horizontal direction between the power-supply voltage VDD lines 101 and ground voltage VSS lines 102.

A P-channel transistor that operates upon being supplied with power-supply voltage VDD is formed in an area 105 that includes the power-supply voltage VDD line 101 in each logic cell CA. An N-channel transistor that operates upon being supplied with ground voltage VSS is formed in an area 106 that includes the ground voltage VSS line 102 in each logic cell CA.

Furthermore, an n-type substrate potential NSUB line 111 and a p-type substrate potential PSUB line 112, which constitute a pair, are formed as a second wiring layer in the vertical direction in FIG. 10 at right angles to the power-supply voltage VDD lines 101 and ground voltage (VSS) lines 102. Substrate-potential supply cells VSC are placed in the areas in which the logic cells CA are placed. The substrate-potential supply cells VSC are disposed one after another in the vertical direction along the n-type substrate potential NSUB line 111 and p-type substrate potential PSUB line 112, and are supplied with an n-type substrate potential NSUB and a p-type substrate potential PSUB from the n-type substrate potential NSUB line 111 and p-type substrate potential PSUB line 112, respectively. The substrate-potential supply cells VSC apply these potentials to N- and P-type substrates, respectively. Adopting such a structure improves area efficiency.

Well known in semiconductor integrated circuit devices is a triple well structure in which a deep N-well is placed at a location deeper than a P-well and N-well that form a transistor [see the specifications of Japanese Patent Kokai Publication Nos. JP-P2004-207749A (FIGS. 21, 23 and 25) and JP-P2002-158293A (FIG. 1), also referred to as Patent Documents 2 and 3, respectively, below]. The semiconductor integrated circuit device described in Patent Document 2 is such that each circuit block is formed on a different deep N-well so that noise produced by each circuit block will not influence other blocks.

In Patent Documents 1 and 2, it is disclosed that N-wells 201 and P-wells 202 are disposed alternatingly in the form of bands, as illustrated in FIG. 11. Standard cells and power-supply cells are disposed at portions spanning the N-wells 201 and P-wells 202.

Patent Document 3 discloses a semiconductor device having dynamic threshold value operating transistors (DTMOS) and variable substrate-bias transistors. The device consumes little power and is highly reliable. This semiconductor device uses 3-layer well regions and element isolation areas and enables a plurality of well regions in which the variable substrate-bias transistors are provided to be made electrically independent with regard to each of the conductivity types. In accordance with this semiconductor device, any number of circuit blocks of variable semiconductor-bias transistors can be formed with regard to each conductivity type, blocks can be divided appropriately into circuit blocks that are to be placed in an active state and circuit blocks that are to be placed in a standby state, and the power consumed by the semiconductor device can be reduced.

[Patent Document 1]

JP Patent Kokai Publication No. JP-P2001-148464A (FIG. 1)

[Patent Document 2]

JP Patent Kokai Publication No. JP-P2004-207749A (FIGS. 21, 23 and 25)

[Patent Document 3]

JP Patent Kokai Publication No. JP-P2002-158293A (FIG. 1)

### SUMMARY OF THE DISCLOSURE

Modern semiconductor integrated circuit devices exhibit a much higher degree of integration and a much greater number of wiring traces. As a result, if a chip of large size is required, this leads directly to a rise in cost. In particular, as the power wiring often involves wiring of large width, the method of routing the power wiring has a major influence upon the increase in degree of integration of the semiconductor integrated circuit device.

In the semiconductor integrated circuit device shown in FIG. 10, the power-supply voltage VDD lines (VDD) 101 and ground voltage VSS lines (GND) 102 are wired in the first wiring layer, and the n-type substrate potential NSUB line 111 and p-type substrate potential PSUB line 112 are wired in the second wiring layer. Generally, in order to assure layout position precision for the wiring of the upper layer, it is necessary to enlarge via diameter or wiring width in the upper wiring layer. Accordingly, if the second wiring layer is made a layer above the first wiring layer (i.e., if it is situated farther from the substrate) in the above-described example, then the degree of integration cannot be raised sufficiently because the wiring will be performed in two layers, namely the first wiring layer and the second wiring layer, which may lower wiring density below that of the first wiring layer.

On the other hand, it is described in Patent Documents 2 and 3 that a deep N-well is placed at a location deeper than an N-well so as to contact the N-well, and that substrate bias in the N-well is controlled. However, with regard to the wiring that supplies the substrate bias, Patent Document 2 does nothing more than disclose performing wiring systematically along the vertical and horizontal directions in the upper layer. Nowhere does Patent Document 3 describe wiring in an upper layer. Neither provides any disclosure whatsoever of a technique that reduces the amount of wiring of a power supply for supplying substrate bias, and the improvement in degree of integration in the semiconductor integrated circuit device is unsatisfactory.

Thus there is much to be desired in the art.

According to a first aspect of the present invention, there is provided a semiconductor integrated circuit device comprising: first well regions of a first conductivity type formed in a substrate; a well region of a second conductivity type formed as a continuum in the substrate so as to surround the first well regions of the first conductivity type when viewed from above the substrate; and a second well region of the first conductivity type formed in the substrate below the first well regions of the first conductivity type and the well region of the second conductivity type. The second well region of the first conductivity type is used as a wiring route regarding a first substrate-bias power supply that is supplied to the first well regions of the first conductivity type, and the well region of the second conductivity type is used as a wiring route regarding a second substrate-bias power supply.

According to a second aspect of the present invention, there is provided a semiconductor integrated circuit device comprising: a semiconductor substrate; a first well region of a first conductivity type formed in the surface of the semiconductor substrate; a second well region of the first conductivity type formed in the surface of the semiconductor substrate in spaced-away relation with respect to the first well region of the first conductivity type; a well region of a second conductivity type provided in the surface of the semiconductor substrate between the first and second well regions of the first conductivity type; a deep well region of the first conductivity type provided below the first and second well regions of the first conductivity type and the well region of the second conductivity type; and power wiring, which is connected to the first well region of the first conductivity type via a well contact, for supplying the first well region of the first conductivity type with substrate bias power. The second well region of the first conductivity type is supplied with substrate bias power from the power wiring through the first well region of the first conductivity type and the deep well region of the first conductivity type.

In the first aspect, it is preferred that the first well regions of the first conductivity type are composed of a plurality of regions in the form of islands, termed “island regions”;

the well region of the second conductivity type is formed in the manner of a sea surrounding the plurality of island regions; and

the first substrate-bias power supply is supplied to some of the plurality of island regions and is supplied to the other regions of these plurality of island regions via the second well region of the first conductivity type.

It is preferred that the device, further comprises:

cell placement areas in which a plurality of standard cells are placed in the form of bands; and

first substrate-bias supply cells, which are placed in the cell placement areas and have one side the height of which is identical with that of the band of the cell placement areas, and apply substrate bias to the standard cells;

wherein the first well regions of the first conductivity type and the well region of the second conductivity type are formed in the cell placement areas; and

the first substrate-bias supply cells are formed in the well region of the second conductivity type and are supplied with the first substrate-bias power supply through the well region of the second conductivity type.

It is preferred that the device further comprises second substrate-bias supply cells, which are placed in the cell placement areas, have one side the height of which is identical with that of the band of the cell placement areas, and apply substrate bias to the standard cells;

wherein the second substrate-bias supply cells are formed in areas that include as least some of the first well regions of the first conductivity type and are supplied with a second substrate-bias power supply through some of the first well regions of the first conductivity type and the second well region of the first conductivity type.

It is preferred that at least some of a plurality of the first substrate-bias supply cells have a diffusion layer of the second conductivity type in the well region of the second conductivity type within the cells, and wiring of the first substrate-bias power supply is routed to the diffusion layer of the second conductivity type via contacts.

It is preferred that at least some of a plurality of the second substrate-bias supply cells have a diffusion layer of the first conductivity type in the first well region of the first conductivity type within the cells, and wiring of the second substrate-bias power supply is routed to the diffusion layer of the first conductivity type via contacts.

In the second aspect, it is preferred that transistors constructing a logic circuit are formed in the first and second well regions of the first conductivity type, respectively.

The meritorious effects of the present invention are summarized as follows.

In accordance with the present invention, much wiring for supplying substrate bias power is eliminated by using the second well region of the first conductivity type and the well region of the second conductivity type as wiring routes regarding the power supply for supplying substrate bias. As a result, the amount of power wiring for supplying substrate bias can be reduced and the degree of integration of the semiconductor integrated circuit device can be raised.

### BRIEF DESCRIPTION OF THE DRAWINGS

FIGS. 1A and 1B are plan and sectional views, respectively, illustrating the structure of a semiconductor integrated circuit device according to a first embodiment of the present invention;

FIGS. 2A and 2B are plan and sectional views, respectively, illustrating the structural details of a portion A in FIG. 1A;

FIGS. 3A and 3B are plan views illustrating the structures of substrate-bias supply cells according to the first embodiment of the present invention;

FIG. 4 is a sectional view illustrating the structure of a semiconductor integrated circuit device according to a second embodiment of the present invention;

FIGS. 5A and 5B are plan views illustrating the structures of substrate-bias supply cells according to the second embodiment of the present invention;

FIG. 6 is a sectional view illustrating the structure of a semiconductor integrated circuit device according to a third embodiment of the present invention;

FIGS. 7A and 7B are plan and sectional views, respectively, illustrating the structural details of a portion B in FIG. 6A;

FIG. 8 is a sectional view illustrating the structure of a semiconductor integrated circuit device according to a fourth embodiment of the present invention;

FIGS. 9A and 9B are plan views illustrating the structures of substrate-bias supply cells according to the fourth embodiment of the present invention;

FIG. 10 is a diagram illustrating the structure of a semiconductor integrated circuit device according to the prior art; and

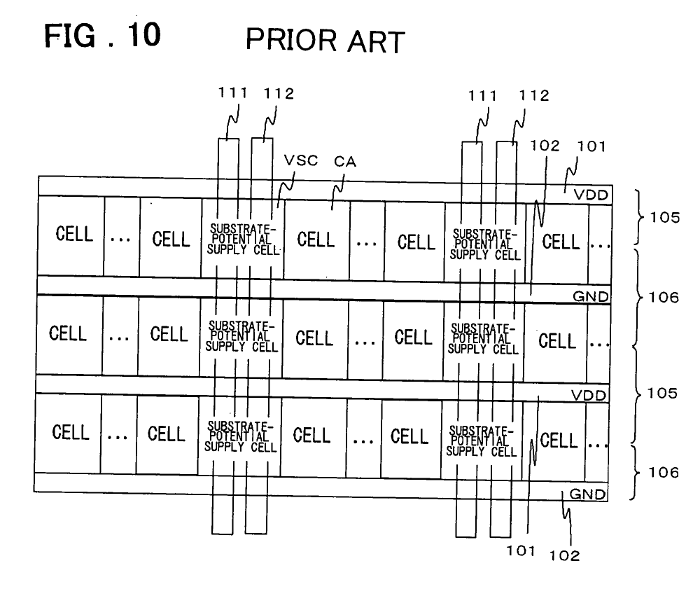

FIG. 11 is a diagram illustrating the well structure of a semiconductor integrated circuit device according to the prior art.

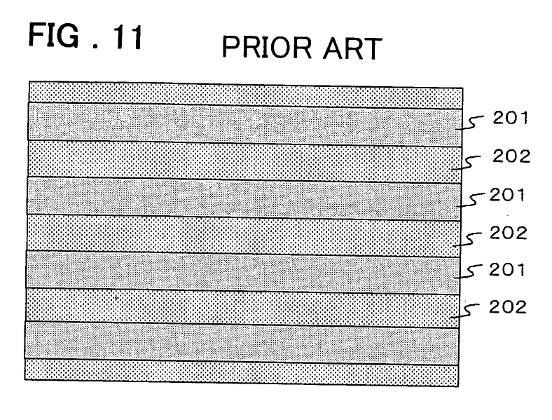

### PREFERRED EMBODIMENTS OF THE INVENTION

Preferred embodiments of the present invention will now be described in detail with reference to the accompanying drawings.

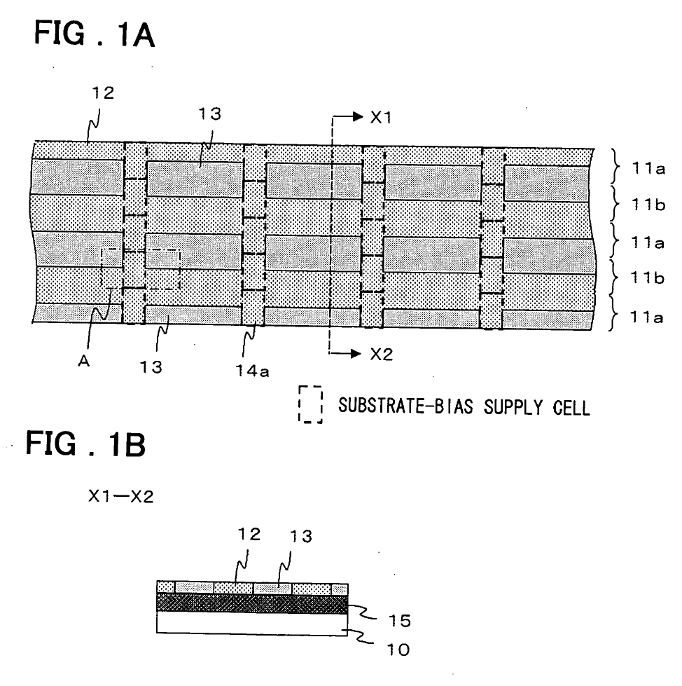

As shown in FIGS. 1A and 1B, a semiconductor integrated circuit device embodying the present invention comprises N-wells 13 formed in a substrate 10; a P-well 12 formed in the substrate 10 as a continuum so as to surround each of the N-wells 13 when viewed from above the substrate; and a deep N-well 15 formed in the substrate 10 below the P-well 12 and N-wells 13. The deep N-well 15 is used as a wiring route regarding a substrate-bias power supply VDD2 supplied to the N-wells 13, and the P-well 12 is used as a wiring route regarding a substrate-bias power supply GND2.

The N-wells 13 may be composed of a plurality of regions in the form of islands (termed as “island regions”), and the P-well 12 may be formed in the manner of a sea encircling (each of) these plurality of regions. The substrate-bias power supply VDD2 is supplied to some of these plurality of island regions and is supplied to the others of these plurality of island regions through the deep N-well 15.

More specifically, the semiconductor integrated circuit device includes cell placement areas 11a, 11b (see FIG. 1) in which a plurality of standard cells are placed in bands on the semiconductor substrate. The semiconductor integrated circuit device comprises N- and P-wells formed in the cell placement areas; and a deep N-well formed at a position deep within the substrate underlying the N- and P-wells. The device further comprises first substrate-bias supply cells 14a (see FIG. 1), which are placed in cell placement areas and have one side the height of which is identical with that of the band of the cell placement area, for applying substrate bias to the standard cells. The first substrate-bias supply cells 14a are formed in the P-well 12 and are supplied with the substrate-bias power supply GND2 through the P-well 12.

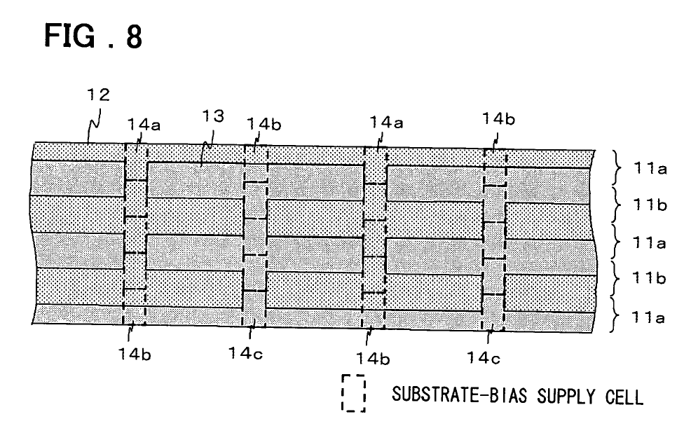

The device may further comprise second substrate-bias supply cells 14b, 14c (see FIG. 8), which are placed in cell placement areas and have one side the height of which is identical with that of the band of the cell placement area, for applying substrate bias to the standard cells. The second substrate-bias supply cells are formed in areas that include at least some of the N-wells and are supplied with the substrate-bias power supply VDD2 through some of the N-wells and the deep N-well.

At least some of a plurality of first substrate-bias supply cells may have a P+ diffusion layer in the P-well in the cells, and the wiring of the substrate-bias power supply GND2 may be routed to the P+ diffusion layer through a contact.

Further, at least some of a plurality of second substrate-bias supply cells may have an N+ diffusion layer in the P-well of the cells, and the wiring of the substrate-bias power supply VDD2 may be routed to the N+ diffusion layer through a contact.

In a semiconductor integrated circuit device having a structure of the kind described above, much wiring for supplying substrate bias power can be eliminated by using the deep N-well and the P-well as wiring routes regarding the power supply for supplying substrate bias. As a result, the degree of integration of the semiconductor integrated circuit device can be raised.

The present invention will now be described in detail in accordance with embodiments with reference to the drawings.

### First Embodiment

FIG. 1A is a plan view illustrating the structure of a semiconductor integrated circuit device according to a first embodiment of the present invention, and FIG. 1B is a sectional view taken along line X1-X2 in FIG. 1A. As shown in FIGS. 1A and 1B, the semiconductor integrated circuit device includes the cell placement areas 11a, 11b in which a plurality of standard cells are placed in bands on the semiconductor substrate 10. The cell placement areas 11a, 11b have the N-wells 13 and P-well 12 (continuously like a sea) formed in the cell placement areas, and the deep N-well 15 formed within the substrate below the N-wells 13 and P-well 12. The device has the substrate-bias supply cells 14a, which are placed in each of cell placement areas 11a, 11b and have one side the height of which is identical with that of the band of the cell placement area, for applying substrate bias to the standard cells. The substrate-bias supply cells 14a extend one after another in the vertical direction and are disposed periodically (with intervals) in the horizontal direction. Although the cell placement areas 11a, 11b structurally are the reverse of each other in the vertically direction, there is no difference in terms of their function.

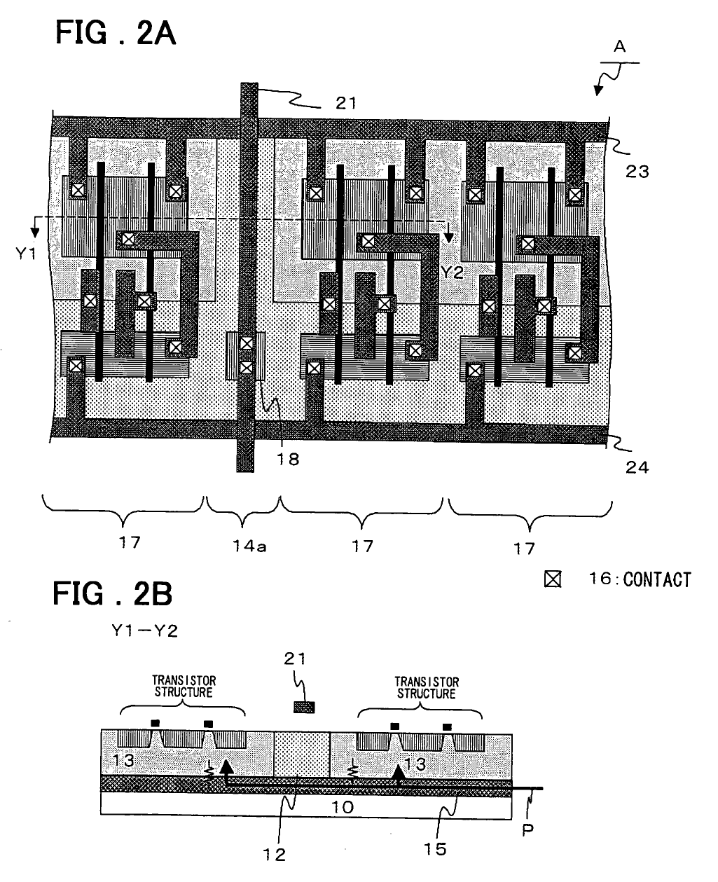

The details of the structure of the semiconductor integrated circuit device will now be described taking a portion A in the cell placement area 11b of FIG. 1A as an example. FIG. 2A is a plan view illustrating in detail the structure of portion A in FIG. 1A, and FIG. 2B is a sectional view taken along line Y1-Y2 in FIG. 2A. As shown in FIG. 2A, three standard cells 17 and the substrate-bias supply cell 14a, which is bracketed by two of the standard cells 17, exist in portion A. Each standard cell 17 exists in a structure in which the N-well 13 and P-well 12 are formed. The standard cell 17 has a VDD wiring trace 23 and a GND wiring trace 24 at upper and lower ends for supplying power, and a transistor group is disposed between the VDD wiring trace 23 and GND wiring trace 24 to thereby form a prescribed logic circuit such as a 2-input NAND gate, by way of example. Routing is performed by metal wiring provided in the upper layer (not shown) in such a manner that desired functions are implemented. It may be so arranged that the VDD wiring trace 23 and GND wiring trace 24 are routed in a first wiring layer nearest to the substrate and are shared as power wiring of neighboring cell placement areas.

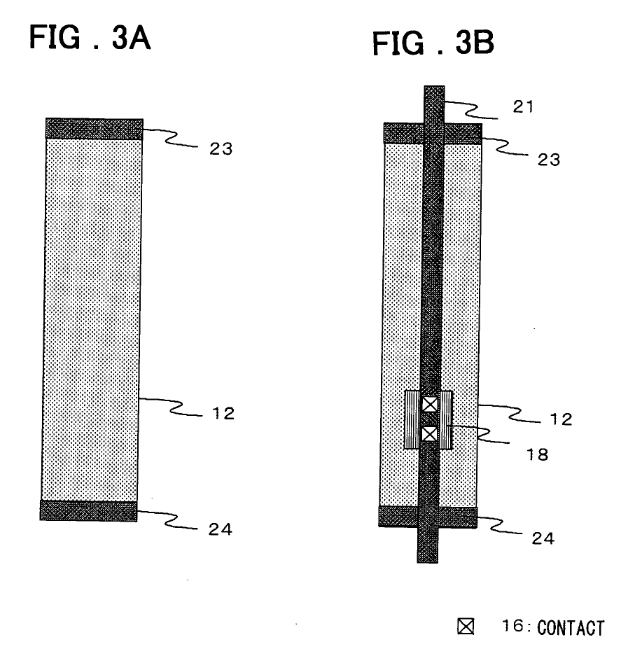

Next, the substrate-bias supply cell 14a will be described. FIGS. 3A and 3B are plan views illustrating structures of the substrate-bias supply cell 14a. FIG. 3A illustrates a cell devoid of a substrate-bias GND2 wiring trace 21, namely a dummy cell. FIG. 3B illustrates a cell in which the substrate-bias GND2 wiring trace 21 exists. The substrate-bias supply cell 14a is formed in the P-well 12 and has the VDD wiring trace 23 and GND wiring trace 24 at its upper and lower ends, respectively, for supplying power. The VDD wiring trace 23 and GND wiring trace 24 are wiring traces for supplying the standard cells 17 with power and are not related directly to the substrate-bias supply cell 14a. The substrate-bias supply cell shown in FIG. 3B further includes a P+ diffusion layer 18 in the P-well 12, unlike the substrate-bias supply cell shown in FIG. 3A. The substrate-bias GND2 wiring trace 21 disposed along the vertical direction is routed to the P+ diffusion layer 18 through contacts 16. It should be noted that the substrate-bias GND2 wiring trace 21 is routed in a second wiring layer farther from the substrate than is the first wiring layer.

The substrate-bias supply cell 14a supplies NMOS-transistor substrate bias power, which can take on a voltage lower than ground voltage supplied to the GND wiring trace 24, from the substrate-bias GND2 wiring trace 21 to the P+ diffusion layer 18 through the contacts and applies this power to the P-well 12. Placing the substrate-bias GND2 wiring trace 21 and the GND wiring trace 24 at the same potential applies substrate bias (back-gate bias) in the forward direction and makes it easier to pass current through the channel of an N-channel transistor (not shown) when the N-channel transistor operates. On the other hand, making the potential of the substrate-bias GND2 wiring trace 21 lower than that of the GND wiring trace 24 applies substrate bias to the P-well 12 and reduces leakage of current when the N-channel transistor is non-operational.

The cell shown in FIG. 3A is used as the substrate-bias supply cells 14a in FIGS. 1A and 1B, and some may be replaced by the cell of FIG. 3B as necessary (it should be noted that the cell shown in FIG. 3B is being used in FIGS. 2A and 2B). That is, in a case where a bias voltage due to the substrate-bias power supply GND2 can be applied to the P-well 12 satisfactorily, e.g., in a case where there is little IR drop, the substrate-bias GND2 wiring trace 21 can be eliminated by using the cell shown in FIG. 3A. This makes it possible to lower the density of wiring in the second wiring layer.

In the semiconductor integrated circuit device of FIGS. 1A and 1B having the structure set forth above, the N-wells 13 are composed of a plurality of regions formed in isolated fashion (in the form of islands, termed “island regions”), and the P-well 12 is formed like a mesh (in the manner of sea) so as to surround these regions. The substrate-bias power supply VDD2 that applies substrate bias to the N-wells 13 is supplied to any N-well 13 via wiring (not shown), as indicated by route P in FIG. 2B, and is supplied to the other N-wells 13 through the deep N-well 15. On the other hand, the substrate-bias power supply GND2 that applies substrate bias to the P-well 12 is supplied via the P-well 12 formed in the mesh-like (sea-like) configuration. Accordingly, both the N-wells 13 and P-well 12 are supplied with the appropriate substrate bias voltages. In a case (location) where the substrate bias voltage is inadequate solely with the mesh-like P-well 12, it will suffice to substitute the cell shown in FIG. 3B.

In accordance with the semiconductor integrated circuit device of this embodiment as set forth above, a great deal of wiring for supplying substrate bias power can be eliminated by using the deep N-well 15 and the mesh-like P-well 12 as a wiring route regarding the power supply for supplying substrate bias. As a result, the degree of integration of the semiconductor integrated circuit device can be raised.

### Second Embodiment

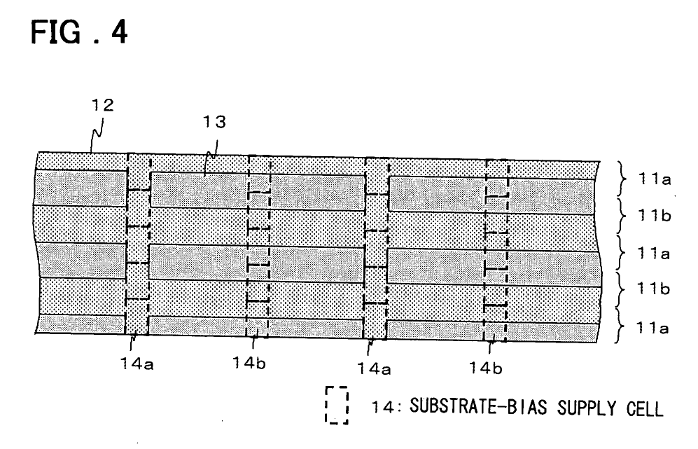

FIG. 4 is a plan view illustrating the structure of a semiconductor integrated circuit device according to a second embodiment of the present invention. The semiconductor integrated circuit device in FIG. 4 has a structure such that among the substrate-bias supply cells 14a in the semiconductor integrated circuit device shown in FIGS. 1A and 1B, those in one of two columns along the horizontal direction are replaced by substrate-bias supply cells 14b. That is, in the cell placement areas 11a, 11b, substrate-bias supply cells 14a, 14b each extend one after another along the vertical direction and are disposed periodically in alternating fashion along the horizontal direction. It should be noted that the substrate-bias supply cell 14a is the cell described in the first embodiment, and the substrate-bias supply cell 14b is a cell that applies bias voltage to the N-wells 13.

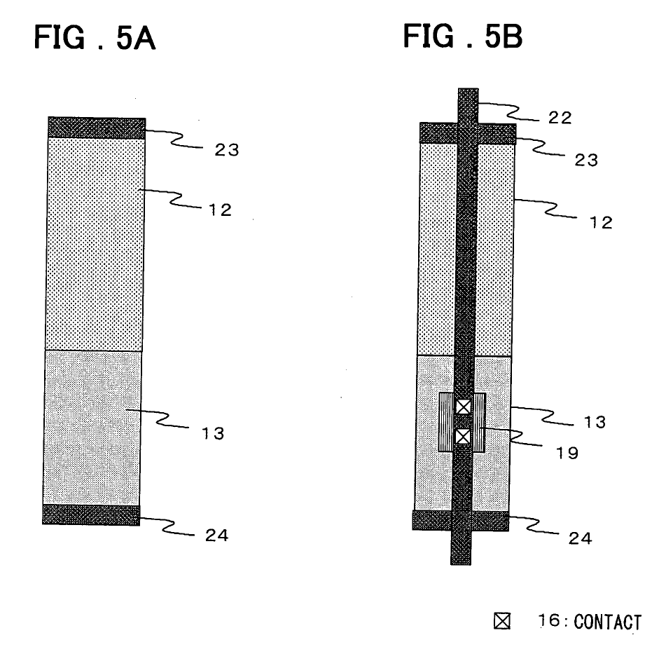

The substrate-bias supply cells 14b will be described next. FIGS. 5A and 5B are plan views illustrating structures of the substrate-bias supply cell 14b. FIG. 5A illustrates a cell devoid of a substrate-bias VDD2 wiring trace 22, namely a dummy cell. FIG. 5B illustrates a cell in which the substrate-bias VDD2 wiring trace 22 exists. Each substrate-bias supply cell 14b exists in a structure in which the N-well 13 and P-well 12 are formed and has the VDD wiring trace 23 and the GND wiring trace 24 at upper and lower ends for supplying power. The VDD wiring trace 23 and the GND wiring trace 24 are wiring traces for supplying the standard cells 17 with power and are not related directly to the substrate-bias supply cell 14b. The substrate-bias supply cell shown in FIG. 5B further includes an N+ diffusion layer 19 in the N-well 13, unlike the substrate-bias supply cell shown in FIG. 5A. The substrate-bias VDD2 wiring trace 22 disposed along the vertical direction is routed to the N+ diffusion layer 19 through contacts 16. The substrate-bias VDD2 wiring trace 22 is routed in a second wiring layer farther from the substrate than is the first wiring layer.

The substrate-bias supply cell 14b supplies PMOS-transistor substrate bias power, which can take on a voltage higher than power-supply voltage supplied to the VDD wiring trace 23, from the substrate-bias VDD2 wiring trace 22 to the N+ diffusion layer 19 through the contacts and applies this power to the N-well 13. Applying a voltage (forward substrate bias) lower than the voltage of the VDD wiring trace 23 to the substrate-bias VDD2 wiring trace 22 makes it easier to pass current through the channel of a P-channel transistor (not shown). On the other hand, making the potential of the substrate-bias VDD2 wiring trace 22 higher than that of the VDD wiring trace 23 applies reverse substrate bias to the N-well 13 and reduces leakage of current when the P-channel transistor is non-operational.

The cell shown in FIG. 5A is used as the substrate-bias supply cells 14b in FIG. 4, and some may be replaced by the cell of FIG. 5B as necessary. That is, in a case where a bias voltage due to the substrate-bias power supply GND2 can be applied to the N-well 13 satisfactorily, e.g., in a case where there is little IR drop in the deep N-well 15, the substrate-bias VDD2 wiring trace 22 can be eliminated by using the cell shown in FIG. 5A. This makes it possible to lower the density of wiring in the second wiring layer.

Further, it may be so arranged that the cell shown in FIG. 3A or FIG. 3B is selected as the substrate-bias supply cell 14a of FIG. 4 in the manner described above in the first embodiment.

In the semiconductor integrated circuit device of FIG. 4 having the structure set forth above, the N-wells 13 are composed of a plurality of (island) regions formed in isolated fashion (in the form of islands) and the P-well 12 is formed as a mesh (in the manner of sea) so as to surround these (island) regions, in a manner similar to that of the first embodiment. The substrate-bias power supply VDD2 that applies substrate bias to the N-wells 13 is supplied to the N-wells 13 via the deep N-well 15. In this case, if it is desired to strengthen the substrate bias of the N-well 13, it will suffice to place many of the substrate-bias supply cells shown in FIG. 5B in the semiconductor integrated circuit device.

### Third Embodiment

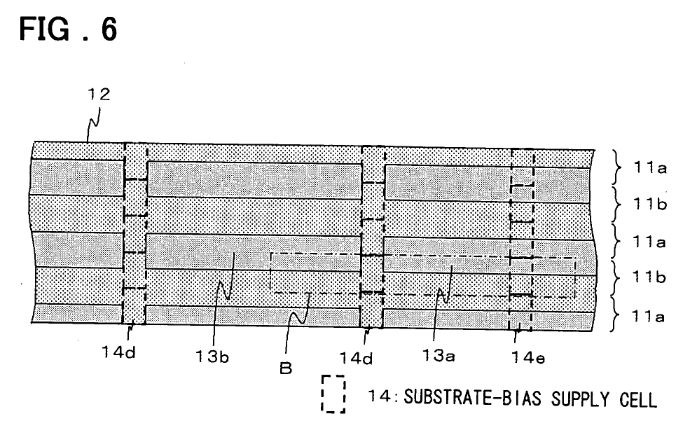

FIG. 6 is a plan view illustrating the structure of a semiconductor integrated circuit device according to a third embodiment of the present invention. The semiconductor integrated circuit device shown in FIG. 6 has a structure such that among the substrate-bias supply cells 14b in the semiconductor integrated circuit device shown in FIG. 4, those in one of two columns along the horizontal direction are eliminated. Further, although substrate-bias supply cells 14d, 14e have a structure substantially equivalent to that of the substrate-bias supply cells 14a, 14b, respectively, shown in FIG. 4, they differ in that they have a diffusion layer for power wiring, as will be described later. It should be noted that among the N-wells 13 shown in FIG. 4, an N-well in an area in which the substrate-bias supply cell 14e exists is an N-well 13a and an N-well not in an area in which the substrate-bias supply cell 14e exists is an N-well 13b.

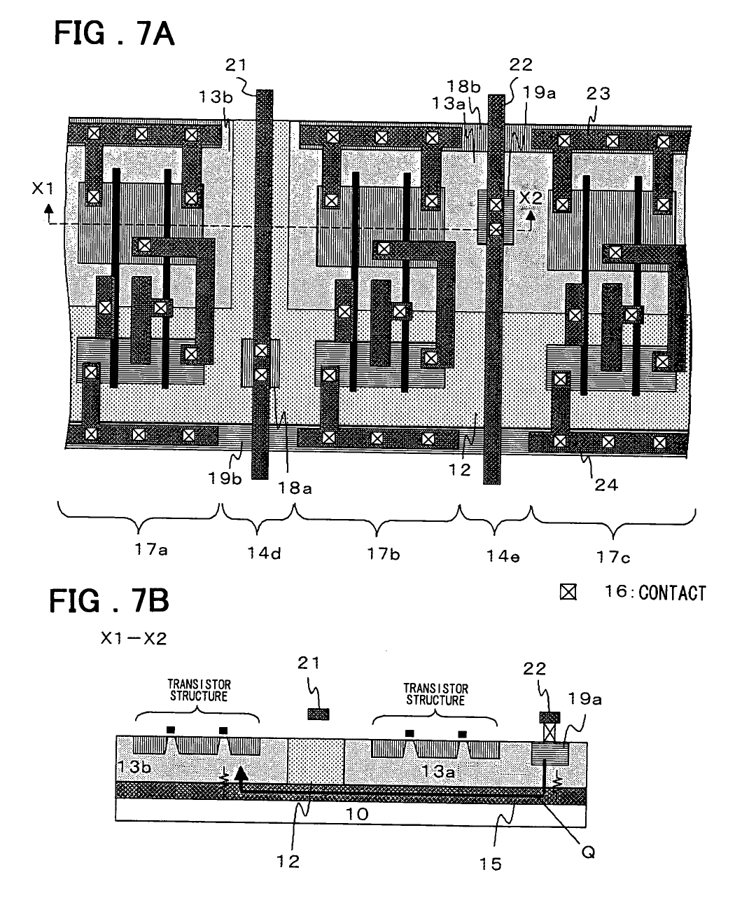

The details of the structure of the semiconductor integrated circuit device will now be described taking as an example a portion B that exists in the cell placement area 11b of FIG. 6. FIG. 7A is a plan view illustrating in detail the structure of portion B in FIG. 7A, and FIG. 7B is a sectional view taken along line X1-X2 in FIG. 7A. As shown in FIG. 7A, three standard cells 17a, 17b, 17c, the substrate-bias supply cell 14d, which is bracketed by the standard cells 17a and 17b, and the substrate-bias supply cell 14e, which is bracketed by the standard cells 17b and 17c, exist in portion B. The standard cells 17a, 17b and 17c have a structure substantially equivalent to that of the standard cell 17 shown in FIGS. 2A and 2B. However, they differ in that the N-wells 13a, 13b underlying the VDD wiring trace 23 extending in the horizontal direction have a P+ diffusion layer 18b and the P-well 12 underlying the GND wiring trace 24 extending in the horizontal direction has an N+ diffusion layer 19b. A transistor group is placed between the VDD wiring trace 23 and the GND wiring trace 24, just as in FIGS. 2A and 2B. This need not be described again. Although only one standard cell exists between the substrate-bias supply cells 14d and 14e in FIGS. 7A and 7B in order to simplify the illustration, it goes without saying that a number of standard cells may exist between the cells 14d and 14e.

The substrate-bias supply cells will be described next. The substrate-bias supply cell 14d is devoid of the VDD wiring trace 23 and GND wiring trace 24, unlike the substrate-bias supply cell shown in FIG. 3B, and the P-well 12 at the position where the GND wiring trace 24 was located has the N+ diffusion layer 19b. The N+ diffusion layer 19b performs the wiring role of the GND wiring 24, which is interrupted along the horizontal direction. It should be noted that the interrupted VDD wiring 23 is assumed to be routed by a higher wiring layer and wiring (not shown) such as detour wiring. The substrate-bias GND2 wiring 21 is assumed to be implemented by a metal wiring layer identical with that of VDD wiring 23 and GND wiring 24.

The substrate-bias supply cell 14d supplies NMOS-transistor substrate bias power, which can take on a voltage lower than ground voltage supplied to the GND wiring trace 24, from the substrate-bias GND2 wiring trace 21 to P+ diffusion layer 18a through the contacts and applies this power to the P-well 12. Placing the substrate-bias GND2 wiring trace 21 and the GND wiring trace 24 at the same potential applies substrate bias (back-gate bias) in the forward direction and makes it easier to pass current through the channel of an N-channel transistor (not shown) when the N-channel transistor operates. On the other hand, making the potential of the substrate-bias GND2 wiring trace 21 lower than that of the GND wiring trace 24 applies substrate bias to the P-well 12 and reduces leakage of current when the N-channel transistor is non-operational.

The substrate-bias supply cell 14e is devoid of the VDD wiring trace 23 and GND wiring trace 24, unlike the substrate-bias supply cell shown in FIG. 5B, and the P-well 12 at the position where the VDD wiring trace 23 was located has the N+ diffusion layer 18b. The N+ diffusion layer 18b performs the wiring role of the interrupted VDD wiring trace 23, and the N+ diffusion layer 19b performs the wiring role of the interrupted GND wiring trace 24. It should be noted that the substrate-bias supply cell 14e is in a positional relationship that is vertically the reverse of that of the substrate-bias supply cell shown in FIG. 5B. The substrate-bias VDD2 wiring trace 22 is assumed to be implemented by a metal wiring layer identical with that of the VDD wiring 23 and GND wiring 24.

The substrate-bias supply cell 14e supplies PMOS-transistor substrate bias power, which can take on a voltage higher than power-supply voltage supplied to the VDD wiring trace 23, from the substrate-bias VDD2 wiring trace 22 to the N+ diffusion layer 19 through the contacts and applies this power to the N-well 13a. Applying a voltage (forward substrate bias) lower than the voltage of the VDD wiring trace 23 to the substrate-bias VDD2 wiring trace 22 makes it easier to pass current through the channel of a P-channel transistor (not shown). On the other hand, making the potential of the substrate-bias VDD2 wiring trace 22 higher than that of the VDD wiring trace 23 applies reverse substrate bias to the N-wells 13a, 13b and reduces leakage of current when the P-channel transistor is non-operational.

In the semiconductor integrated circuit device having the structure set forth above, the N-well 13a and N-well 13b are spaced away from each other and the P-well 12 is disposed between them. The substrate-bias power supply VDD2 that applies substrate bias to the N-well 13a is supplied to the N-well 13a from the substrate-bias VDD2 wiring trace 22 via contacts and the N+ diffusion layer 19a, as indicated by route Q in FIG. 7B, and is supplied to the other N-well 13b through the deep N-well 15. On the other hand, the substrate-bias power supply GND2 that applies substrate bias to the P-well 12 is supplied via the P-well 12 formed in the mesh-like (sea-like) configuration. Accordingly, the N-wells 13a, 13b and P-well 12 are supplied with the appropriate substrate bias voltages.

In accordance with the semiconductor integrated circuit device of this embodiment as set forth above, a great deal of wiring for supplying substrate bias power can be eliminated by using the deep N-well 15 and the mesh-like P-well 12 as a wiring route regarding the power supply for supplying substrate bias. Furthermore, the substrate-bias GND2 wiring trace 21, substrate-bias VDD2 wiring trace 22, VDD wiring trace 23 and GND wiring trace 24 are routed in the same metal wiring layer. As a result, the amount of wiring can be reduced and the degree of integration of the semiconductor integrated circuit device raised.

### Fourth Embodiment

FIG. 8 is a plan view illustrating the structure of a semiconductor integrated circuit device according to a fourth embodiment of the present invention. The semiconductor integrated circuit device shown in FIG. 8 has a structure such that among the substrate-bias supply cells 14a in the semiconductor integrated circuit device shown in FIG. 4, those substrate-bias supply cells 14a contained in the cell placement area 11a at the lowermost end are replaced by the substrate-bias supply cells 14b. Further, among the substrate-bias supply cells 14b in the semiconductor integrated circuit device shown in FIG. 4, those substrate-bias supply cells 14b contained in the cell placement areas other than the cell placement area 11a at the uppermost end are replaced by substrate-bias supply cells 14c. The substrate-bias supply cells 14c are cells that apply bias voltage to the N-well 13.

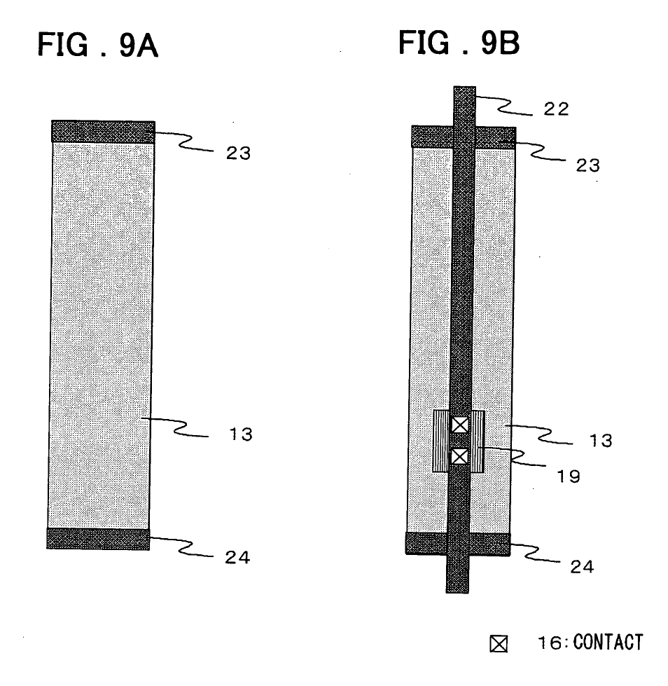

The substrate-bias supply cells 14c will be described next. FIGS. 9A and 9B are plan views illustrating structures of the substrate-bias supply cell 14c. FIG. 9A illustrates a cell devoid of the substrate-bias VDD2 wiring trace 22, namely a dummy cell. FIG. 9B illustrates a cell in which the substrate-bias VDD2 wiring trace 22 exists. Each substrate-bias supply cell 14c exists in a structure in which the N-well 13 is formed and has the VDD wiring trace 23 and the GND wiring trace 24 at upper and lower ends for supplying power. The VDD wiring trace 23 and the GND wiring trace 24 are wiring traces for supplying the standard cells 17 with power and are not related directly to the substrate-bias supply cell 14c. The substrate-bias supply cell shown in FIG. 9B has an N+ diffusion layer 19 in the N-well 13, unlike the substrate-bias supply cell shown in FIG. 9A. The substrate-bias VDD2 wiring trace 22 is routed to a second wiring layer farther from the substrate than is the first wiring layer. The substrate-bias supply cell 14c functions in a manner similar to that of the substrate-bias supply cell 14b described above in conjunction with FIGS. 3A and 3B.

The cell shown in FIG. 9A is used as the substrate-bias supply cells 14c in FIG. 8, and some may be replaced by the cell of FIG. 9B as necessary. That is, in a case where a bias voltage due to the substrate-bias power supply GND2 can be applied to the N-well 13 satisfactorily, e.g., in a case where there is little IR drop in the deep N-well 15, the substrate-bias VDD2 wiring trace 22 can be eliminated by using the cell shown in FIG. 9A. This makes it possible to lower the density of wiring in the second wiring layer.

Further, it may be so arranged that the cell shown in FIG. 3A or FIG. 3B is selected as the substrate-bias supply cell 14a of FIG. 8 in the manner described above in the first embodiment. Furthermore, it may be so arranged that the cell shown in FIG. 5A or FIG. 5B is selected as the substrate-bias supply cell 14b of FIG. 8 in the manner described above in the second embodiment.

In the semiconductor integrated circuit device of FIG. 8 having the structure set forth above, the N- and P-wells 13 and 12, respectively, are formed so as to surround each other (or intermeshing together). The substrate-bias power supply VDD2 that applies substrate bias to the N-well 13 is supplied to the N-well 13 via the deep N-well 15. In this case, if it is desired to strengthen the substrate bias of the N-well 13, it will suffice to place many of the substrate-bias supply cells shown in FIG. 5B or FIG. 9B in the semiconductor integrated circuit device.

As many apparently widely different embodiments of the present invention can be made without departing from the spirit and scope thereof, it is to be understood that the invention is not limited to the specific embodiments thereof except as defined in the appended claims.

It should be noted that other objects, features and aspects of the present invention will become apparent in the entire disclosure and that modifications may be done without departing the gist and scope of the present invention as disclosed herein and claimed as appended herewith.

Also it should be noted that any combination of the disclosed and/or claimed elements, matters and/or items may fall under the modifications aforementioned.

What is claimed is:

1. A semiconductor integrated circuit device comprising:
first well regions of a first conductivity type formed in a substrate;
a well region of a second conductivity type formed as a continuum in the substrate so as to surround said first well regions of the first conductivity type when viewed from above the substrate; and
a second well region of the first conductivity type formed in the substrate below said first well regions of the first conductivity type and said well region of the second conductivity type;
wherein said second well region of the first conductivity type is used as a wiring route regarding a first substrate-bias power supply that is supplied to said first well regions of the first conductivity type, and said well region of the second conductivity type is used as a wiring route regarding a second substrate-bias power supply.

2. The device according to claim 1, wherein said first well regions of the first conductivity type are composed of a plurality of regions in the form of islands, termed “island regions”;
said well region of the second conductivity type is formed in the manner of a sea surrounding said plurality of island regions; and
the first substrate-bias power supply is supplied to some of said plurality of island regions and is supplied to the other regions of these plurality of island regions via said second well region of the first conductivity type.

3. The device according to claim 1, further comprising:
cell placement areas in which a plurality of standard cells are placed in the form of bands; and
first substrate-bias supply cells, which are placed in said cell placement areas and have one side the height of which is identical with that of the band of said cell placement areas, and apply substrate bias to the standard cells;
wherein said first well regions of the first conductivity type and said well region of the second conductivity type are formed in said cell placement areas; and
said first substrate-bias supply cells are formed in said well region of the second conductivity type and are supplied with the first substrate-bias power supply through said well region of the second conductivity type.

4. The device according to claim 2, further comprising:
cell placement areas in which a plurality of standard cells are placed in the form of bands; and
first substrate-bias supply cells, which are placed in said cell placement areas and have one side the height of which is identical with that of the band of said cell placement areas, and apply substrate bias to the standard cells;
wherein said first well regions of the first conductivity type and said well region of the second conductivity type are formed in said cell placement areas; and
said first substrate-bias supply cells are formed in said well region of the second conductivity type and are supplied with the first substrate-bias power supply through said well region of the second conductivity type.

5. The device according to claim 3, further comprising second substrate-bias supply cells, which are placed in said cell placement areas, have one side the height of which is identical with that of the band of said cell placement areas, and apply substrate bias to the standard cells;
wherein said second substrate-bias supply cells are formed in areas that include as least some of said first well regions of the first conductivity type and are supplied with a second substrate-bias power supply through some of said first well regions of the first conductivity type and said second well region of the first conductivity type.

6. The device according to claim 4, further comprising second substrate-bias supply cells, which are placed in said cell placement areas, have one side the height of which is identical with that of the band of said cell placement areas, and apply substrate bias to the standard cells;
wherein said second substrate-bias supply cells are formed in areas that include as least some of said first well regions of the first conductivity type and are supplied with a second substrate-bias power supply through some of said first well regions of the first conductivity type and said second well region of the first conductivity type.

7. The device according to claim 3, wherein at least some of a plurality of said first substrate-bias supply cells have a diffusion layer of the second conductivity type in said well region of the second conductivity type within the cells, and wiring of said first substrate-bias power supply is routed to the diffusion layer of the second conductivity type via contacts.

8. The device according to claim 4, wherein at least some of a plurality of said first substrate-bias supply cells have a diffusion layer of the second conductivity type in said well region of the second conductivity type within the cells, and wiring of said first substrate-bias power supply is routed to the diffusion layer of the second conductivity type via contacts.

9. The device according to claim 5, wherein at least some of a plurality of said second substrate-bias supply cells have a diffusion layer of the first conductivity type in said first well region of the first conductivity type within the cells, and wiring of said second substrate-bias power supply is routed to the diffusion layer of the first conductivity type via contacts.

10. The device according to claim 6, wherein at least some of a plurality of said second substrate-bias supply cells have a diffusion layer of the first conductivity type in said first well region of the first conductivity type within the cells, and wiring of said second substrate-bias power supply is routed to the diffusion layer of the first conductivity type via contacts.

11. A semiconductor integrated circuit comprising:
a semiconductor substrate;
a first well region of a first conductivity type formed in the surface of said semiconductor substrate;
a second well region of the first conductivity type formed in the surface of said semiconductor substrate in spaced-away relation with respect to said first well region of the first conductivity type;
a well region of a second conductivity type provided in the surface of said semiconductor substrate between said first and second well regions of the first conductivity type;
a deep well region of the first conductivity type provided below said first and second well regions of the first conductivity type and said well region of the second conductivity type; and
power wiring, which is connected to said first well region of the first conductivity type via a well contact, for supplying said first well region of the first conductivity type with substrate bias power;
wherein said second well region of the first conductivity type is supplied with the substrate bias power from said power wiring through said first well region of the first conductivity type and said deep well region of the first conductivity type.

12. The circuit according to claim 11, wherein transistors constructing a logic circuit are formed in said first and second well regions of the first conductivity type, respectively.
